(19) United States
(12) Patent Application Publication
(10) Pub. No.: US 2017/0303439 A1
(43) Pub. Date: Oct. 19, 2017

(54) MODULAR UTILITIES

(71) Applicant: HEWLETT PACKARD ENTERPRISE DEVELOPMENT LP, Houston, TX (US)

(72) Inventors: Tahir CADER, Liberty Lake, WA (US); John P FRANZ, Houston, TX (US); Wade D VINSON, Magnolia, TX (US); Arlen L ROESNER, Fort Collins, CO (US); Kevin B LEIGH, Houston, TX (US); Dave MAYER, Fort Collins, CO (US)

(21) Appl. No.: 15/512,023

(22) PCT Filed: Sep. 30, 2014
(86) PCT No.: PCT/US2014/058498

§ 371 Date: Mar. 16, 2017

(51) Int. Cl. H05K 7/20; H05K 7/14; H01R 13/00

(52) U.S. Cl. CPC H05K 7/20736; H05K 7/20836; H01R 13/005; H05K 7/1492; H05K 7/20781

(57) ABSTRACT

A modular utility assembly is provided herein. The modular utility assembly includes a power module, a network module, and a cooling module. The power module includes a power connector to mate with and provide power to an electronic module. The network module includes a network connector to mate with and provide a network connection between the network module and the electronic module. The cooling module includes a cooling connector to mate with and connect to a cooling component on the electronic module.

### BACKGROUND

Electronic devices have temperature, communication, and power requirements. As the density of the electronic devices increase, the utilities associated therewith may need to be adapted or changed to efficiently handle the temperature, communication, and power requirements.

### BRIEF DESCRIPTION OF THE DRAWINGS

Non-limiting examples of the present disclosure are described in the following description, read with reference to the figures attached hereto and do not limit the scope of the claims. In the figures, identical and similar structures, elements or parts thereof that appear in more than one figure are generally labeled with the same or similar references in the figures in which they appear. Dimensions of components and features illustrated in the figures are chosen primarily for convenience and clarity of presentation and are not necessarily to scale. Referring to the attached figures:

FIG. 1 illustrates a block diagram of a modular utility assembly according to an example;

FIG. 2 illustrates a top view of the assembly of FIG. 1 according to an example;

FIG. 3 illustrates a block diagram of a modular computing system according to an example;

FIG. 4 illustrates an exploded view of the system of FIG. 3 according to an example;

FIG. 5 illustrates a front view of the system of FIG. 3 according to an example;

FIG. 6 illustrates a back view of the system of FIG. 3 according to an example;

FIG. 7 illustrates a block diagram of the modular computing system according to a further example; and

FIGS. 8-9 illustrate schematic views of the system of FIG. 7 according to an example.

### DETAILED DESCRIPTION

In the following detailed description, reference is made to the accompanying drawings which form a part hereof, and in which is depicted by way of illustration specific examples in which the present disclosure may be practiced. It is to be understood that other examples may be utilized and structural or logical changes may be made without departing from the scope of the present disclosure.

Electronic system designs must balance conflicts between power density, spatial layout, temperature requirements, acoustic noise, and other factors. Air cooling systems typically use heat sinks and fans to remove “waste” heat from the system. The use of heat sinks and fans increase the electrical power required to operate an electronic device in an electronic system, and may cause excessive acoustic noise and lower system density. Liquid cooling can be more efficient than air cooling; however, the liquid cooling typically includes plumbing connections within the electronic devices. As the liquid goes through the plumbing connections the risk of leakage of liquid within the electronic device is introduced.

Custom cooling solutions may be configured for cooling electronic systems, such as modular computing facilities. Custom cooling solutions may include air cooling systems and/or liquid cooling systems. The connections used to make the cooling systems work are custom to the design of the facility and typically are not interchangeable or compatible with one another. Custom cooling solutions are not cost effective and do not allow for standardization of equipment or use of off the shelf components. Moreover, the use of custom solutions may complicate installation and/or delay repair times.

In examples, a modular utility assembly is provided. The modular utility assembly includes a power module, a network module, and a cooling module. The power module includes a power connector to mate with and provide power to an electronic module. The network module includes a network connector to mate with and provide a network connection between the network module and the electronic module. The cooling module includes a cooling connector to mate with and connect to a cooling component on the electronic module. The modular utility assembly provides a standard platform for the electronic module. Moreover, the connectors allow for a standardized set of connections to connect the utilities, such as power, network, and/or cooling modules to the electronic module without increasing the cost to deploy and maintain the utilities and the electronic module.

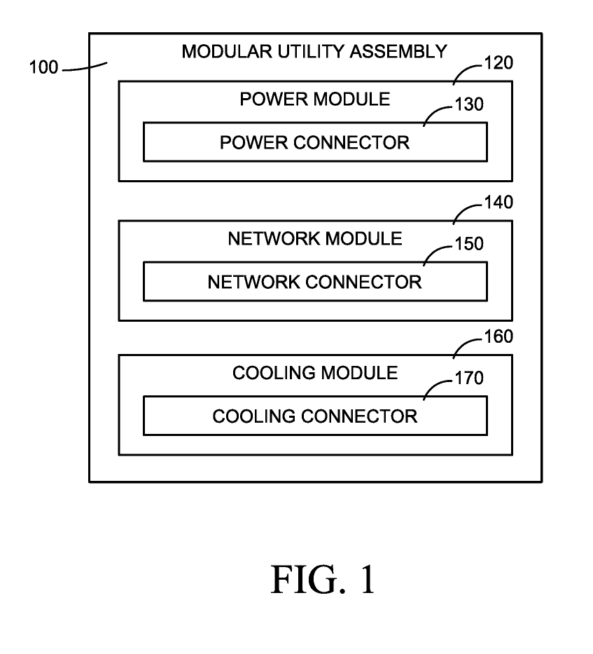

FIG. 1 illustrates a block diagram of a modular utility assembly 100 according to an example. The modular utility assembly 100 includes a power module 120, a network module 140, and a cooling module 160. The power module 120 includes a power connector 130 to mate with and provide power to an electronic module. The network module 140 includes a network connector 150 to mate with and provide a network connection between the network module 140 and the electronic module. The cooling module 160 includes a cooling connector to mate with and connect to a cooling component on the electronic module. The power module 120, the network module 140, and the cooling module 160 may each form columns within the modular utility assembly 100 as singular modules or column structures and/or as a plurality of modules linked together to form a column structure.

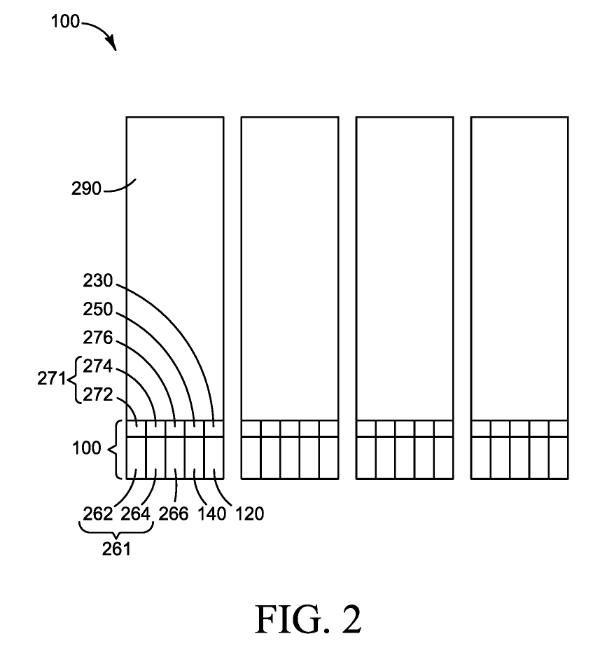

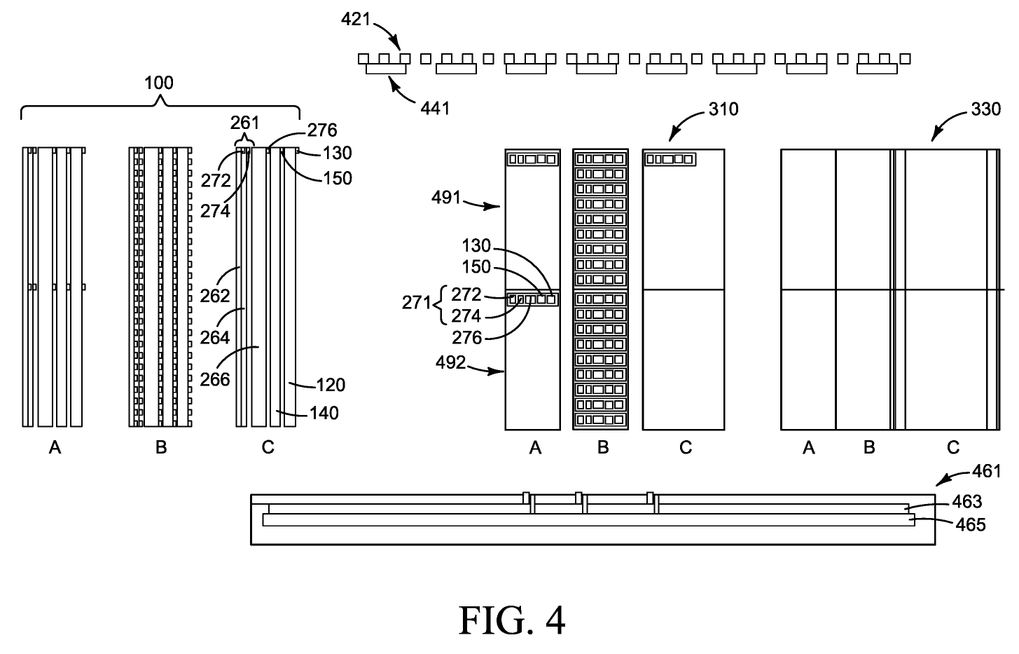

FIG. 2 illustrates a top view of the assembly 100 of FIG. 1 according to an example. Referring to FIG. 2, the modular utility assembly 100 may include the power module 120, the network module 140, and the cooling module 160 aligned in a columnar arrangement with each of the power module 120, the network module 140, and the cooling module 160 connection to at least one electronic module 290. FIG. 2 illustrates four (4) modular utility assemblies 100 and four (4) electronic modules 290, such as servers. A plurality of modular utility assemblies 100 provides redundancy and scalability for the overall system that the modular utility assembly 100 is connected to. Moreover, each of the power module 120, the network module 140, and the cooling module 160 include a connection to a plurality of electronic modules 290. For example, the connection may be formed at the rack level, server level, and/or blade level as illustrated in FIG. 4.

The connections are made with a set of blind mate connections, such as a power blind mate connector 230, a network blind mate connector 250, and/or a cooling bind mate connector 270, that connect the electronic module 290 to the power module 120, the network module 140, and the cooling module 160. The phrases “blind mate connection” and “blind mate connector” refer to connections and/or connectors that do not require tools to form a connection and include self -aligning features.

The electronic modules 290, the power modules 120, the network modules 140, and the cooling modules 160 may each include a blind mate connector to mate with the blind mate connectors of the electronic module 290. Alternatively, manual connections and/or a combination of manual and blind mate connections may connect the power module 120, the network module 140, and the cooling module 160 to the electronic module 290.

The power module 120 may include, for example, a high voltage direct current (HVDC) power supply, a high voltage alternating current supply (HVAC), an alternating current (AC) power supply, a direct current (DC) power supply, a DC-DC current converter module, an auxiliary DC power supply, and/or power fuse blocks. The power module 120 is illustrated in a position opposite the liquid cooling module 161; however, the power module 120 may be positioned adjacent to a supply in order to provide heat removal via a dry disconnect thermal contact connection (dry disconnect assembly).

The network module 140 may include, optical or electric signal paths. For example, an input/output (I/O) communication connection that are optical or electrical, which connect the module to a top of rack (ToR) or end of rack (EoR) switch with line cards, plenums with optical and/or electrical fabrics and/or a controller.

FIG. 2 illustrates the cooling modules 160 as including a liquid cooling module 261 and an air cooling module 266. The phrase “liquid cooling module” refers to a cooling system to cool an electronic module using liquid. The phrase “air cooling module” refers to a cooling system to cool an electronic module using thermal and mechanical means. The liquid cooling module 261 may include a liquid supply 262 connected to a liquid cooling supply connector 272 and a liquid return 264 connected to a liquid cooling return connector 274. For example, the cooling supply connector 272 and the liquid cooling return 274 may each be blind mate connections at various location adjacent to the electronic module, such as the back, front, sides, top, or bottom of the electronic module 290. The liquid cooling module 261 may alternatively include a dry disconnect assembly with a heat sink to receive heat from the electronic module 290 and a liquid cooling loop to remove the heat from the heat sink.

In a further example, the liquid cooling module 261 may not be linked to an open liquid feed (i.e., a water feed), but may include a water to water heat exchange assembly that provides a closed liquid loop within the electronic module(s) 290, i.e., within a server. Furthermore, the liquid cooling module 261 may include hot swappable pumps that circulate liquid within the electronic module 290 or server and eliminate the internal server device level pumps. The terms “swappable” or “hot swappable” refer to interchangeability of components without requiring a system to reboot.

The air cooling module 266 may include a set of fans that connect to the electronic module 290 through a set of electrical blind mate connectors which bring power to fans, referred to as an air connector 276 or an air blind mate connector.

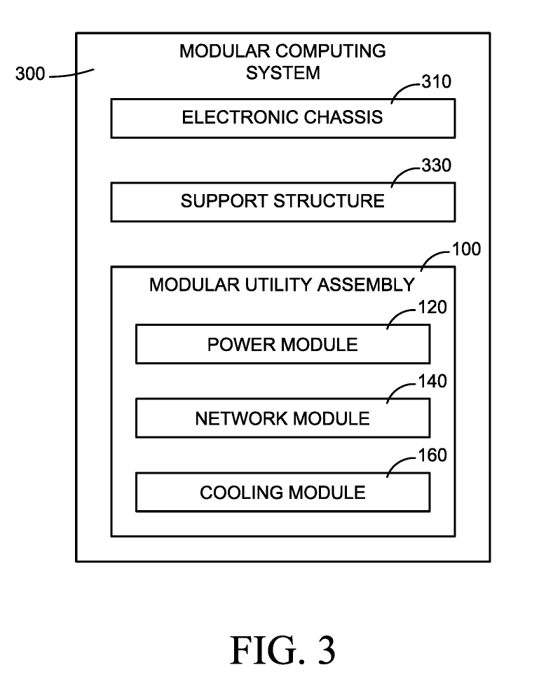

FIG. 3 illustrates a block diagram of a modular computing system 300 according to an example. The modular computing system 300 includes a modular utility assembly 100, an electronic chassis 310, and a support structure 330. The modular utility assembly 100 includes a power module 120, a network module 140, and a cooling module 160, each having a set of blind mate connectors, such as a power blind mate connector 230, a network blind mate connector 250, and a cooling bond mate connector 270. The electronic chassis 310 to receive an electronic module 290 and connect the electronic module 290 to the modules of the modular utility assembly via the set of blind mate connectors. The support structure 330 to receive the modular utility assembly 100 and the electronic chassis 310.

FIG. 4 illustrates an exploded view of the back side of the system of FIG. 3 according to an example. The modular computing system 300 is illustrated to include the modular utility assembly 100, the electronic chassis 310, and the support structure 330. The electronic module and the chassis is illustrated as receiving three racks of electronic modules, for example, A, B, and C.

The modular utility assembly 100 includes a power module 120, a network module 140, and a cooling module 160. The power module 120 includes a power connector 130, such as a blind mate power connector 230. For example, the power module 120 may include a HVDC power supply. The power may be provided to the modular utility assembly 100 through a power busbar 421 or power manifold connected to the modular utility assembly 100 to provide power to the electronic modules 290.

The network module 140 includes a network connector 150, such as a network blind mate connector 250. For example, the network connector 150 may include an input/output communication network. The network module 140 may be connected to a network manifold 441 that provides network communication for the electronic modules 290. The network manifold 441 is illustrated as a horizontal module that carries aggregated sets of communication from multiple network modules 140. For example, the network manifold 441 may include optical fibers or electrical wires.

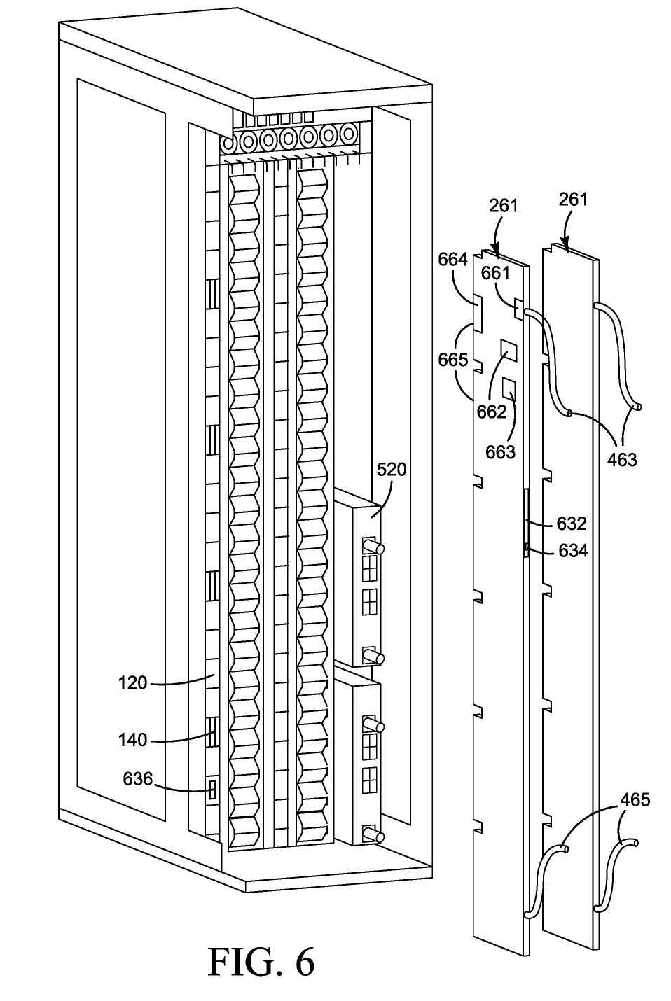

The network module 140 may also provide a connection to a controller and single point to perform diagnostics on the system, including the modular utility assembly 100 and/or the electronic module 290. For example, external diagnostics and interactive functionality, such as indicators for server identification, health status, power, power breakers, liquid breakers, valves, pressure gauges, and/or network ports for linking electronic modules 290 to form for example, server zones. In other examples, a display to provide external diagnostics and interactive functionality features. For example, the modular computing system 300 may include a display device to provide indicators on the status of the modular computing system 300 and modules connected thereto. The network module 140 may also be connected to a removal request button, along with corresponding removal pending and approval indicators, for each modular utility assembly 100. Examples are illustrated in FIG. 6 below.

The cooling module 160 is illustrated to include a liquid cooling module 261 and an air cooling module 266. The liquid cooling module 261 includes a liquid supply 262 and a liquid return 264. The liquid supply 262 to connect to the liquid cooling supply connector 272. The liquid return 264 to connect to the liquid cooling return connector 274. The liquid cooling module 261 may be connected to a cooling manifold 461 that includes a horizontal module that carries a liquid or fluid to and from the cooling modules 160 using a supply line 463 and a return line 465. The cooling manifold 461 to provide a liquid or fluid to the modular utility assembly 100. The air cooling module 266 may include a column of cooling modules, such as fans connected to the electronic module 290 through a set of electrical blind mate connectors which bring power to the fans, referred to as the air connector 276.

As illustrated in FIG. 4, the blind mate connections may be formed at the rack level, server level, blade level and/or cartridge level. The modular utilities reduce clutter, waste, and damage to wires, fibers, and/or lines. For example, the rack A includes the modular utility assembly 100 connecting to the rack at two locations to provide server level connections for the top group of servers 491 and the bottom group of servers 492. Rack B illustrates the blind mate connections at the blade or cartridge level, with each blade or cartridge including a connection. A further example is illustrated in rack C where one connection is provided for the whole column of the rack to provide rack level blind mate connections.

Moreover, the blind mate connections are illustrated in the back of the racy with the modular utility assembly 100 in the back; however, the modular utility assembly 100 may also be located in the front, side, top, or bottom of the rack depending on the rack and/or server design. The modular utility assembly 100 may reduce clutter at the rack and/or server level. For example, the modular utility assembly 100 may include linkable or smaller pieces that may be small than the size of the rack or the server they connect to. The linkable or smaller pieces may be premade or assembled to protect the contents of the lines and provide an easy and efficient way to safely manage the connections and allow for safety certification, in assemblies with, for instance, high voltage power supplies. The linkable or smaller pieces may contain sensor devices, such as temperature sensors, flow rate and/or pressure sensors, and leak sensors, where these sensor devices may be coupled to management controllers via wires or wireless network. Furthermore, the linkable pieces make installation easier, which improve the handling and reduces the installation and replacement costs. For example, the power, pressure, and/or signal components may be pre-built and tested prior to installations, which decreases labor costs, can avoid waste, excess wire length, and damage, and may be more adaptable for replacements, repairs, and upgrades.

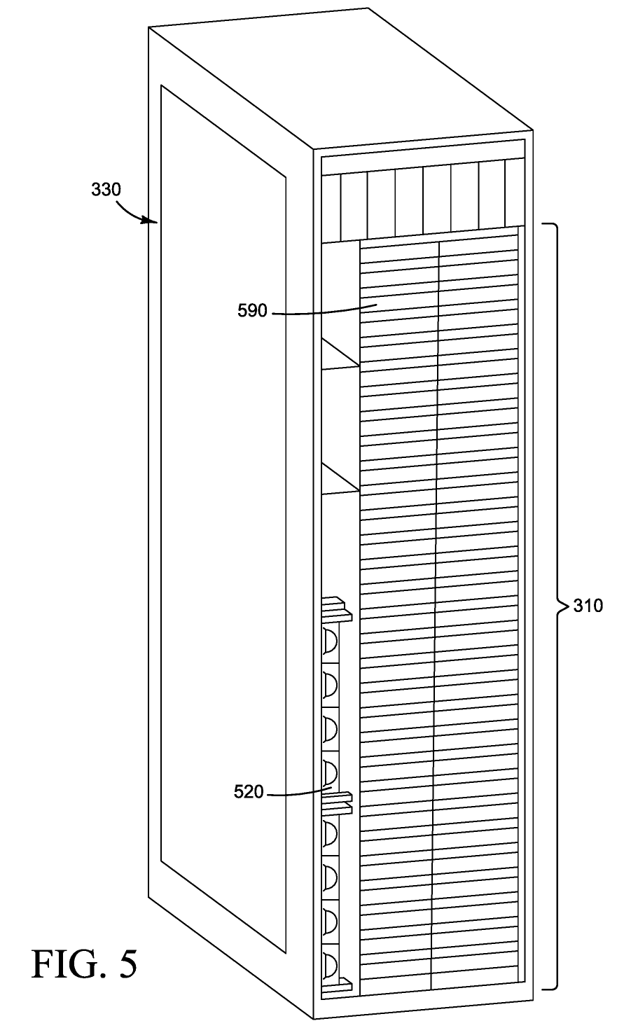

FIG. 5 illustrates a front view of the system of FIG. 3 according to an example. The electronic modules 290 are illustrated as blade servers 590. The electronic modules 290 may alternatively include a tray of server cartridges. The front view also illustrates a modular power cartridge 520 positioned next to the blade servers 590 to provide power to the blade servers 590 through an interface in the back of the blade servers 590. The interface to distribute the power from the modular power cartridge 520 to the blade servers 590. The module power cartridges 520 are illustrated an example of a set of linkable power module. The module power cartridges 520 may further include power breakers and/or sensors connected to controllers to manage the power supplies.

FIG. 6 illustrates a back view of the modular computing system 300 of FIG. 3 according to an example. The modular utility assembly 100 includes liquid cooling modules 261 with a first set of integrated dry disconnect fittings 665. For example, the dry disconnect fittings may include a heat sink to mate with the electronic modules 290, i.e., blade servers 590, such that the heat sink receives the heat from the electronic modules 290 and removes the heat from the liquid cooling modules 261 using a fluid or liquid. For example, the liquid may enter the liquid cooling module 261 through a liquid supply 463 illustrated on the top of the liquid cooling module 261, which is illustrated as a column in FIG. 6. The liquid may be distributed through the liquid cooling modules 261 in supply channels that carry the liquid over the heat sink to remove the heat and then remove the heated liquid through return channels. From the return channels, the liquid may be removed from the liquid cooling module 261 through the liquid return 465 illustrated on the bottom of the liquid cooling module 261. The liquid cooling module 261 may include valves 661, liquid breakers 662, flow and pressure gauges 663, and/or temperature sensors 664.

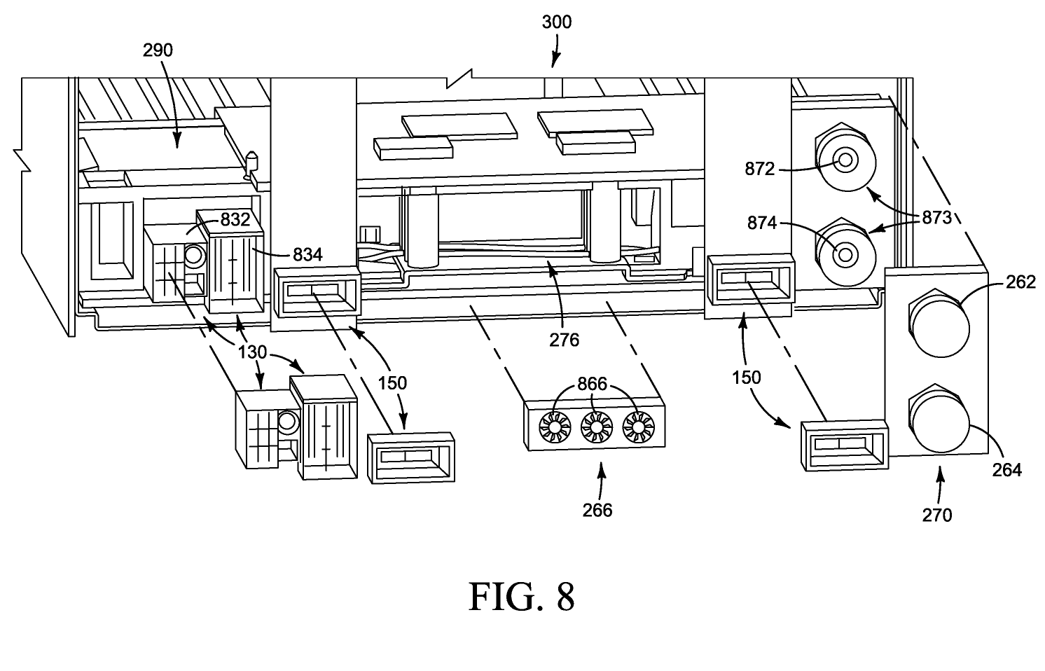

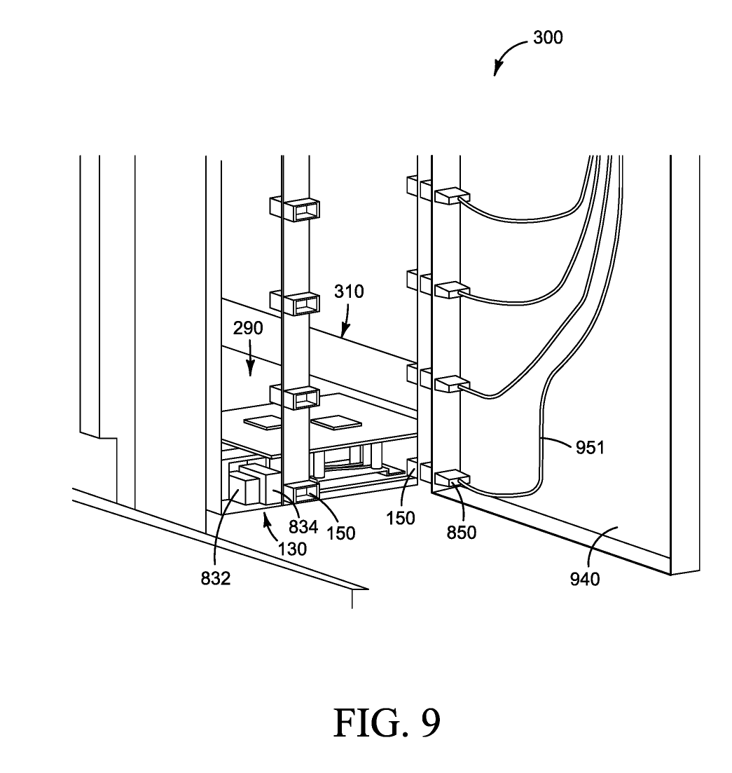

To mate the liquid cooling modules 261, the electronic chassis accepts a set of electronic modules 290 with a second set of integrated dry disconnect cooling fittings. The first set of integrated dry disconnect fittings 665 and the second set of dry disconnect cooling fittings to mate. For example, both fittings may lie flush with one another to facilitate the transfer of heat therebetween. Alternatively, the dry disconnect cooling fittings may include a male member and a female member formed to mate with another and transfer heat therebetween. Moreover, as illustrated in FIGS. 8-9 below the liquid cooling modules 261 may connect using blind mate connectors with cold plates instead of a dry disconnect fitting 665.

The modular computing system 300 may further include a display 632 or visual indicators, such as a removal request button 636 to coordinate removal and replacement of the modules connected to the modular computing system 300. For example, there may be a removable request button 636 on one or more modules and/or on the display 632 and corresponding removal pending and approval indicators 634, for each modular utility assembly 100.

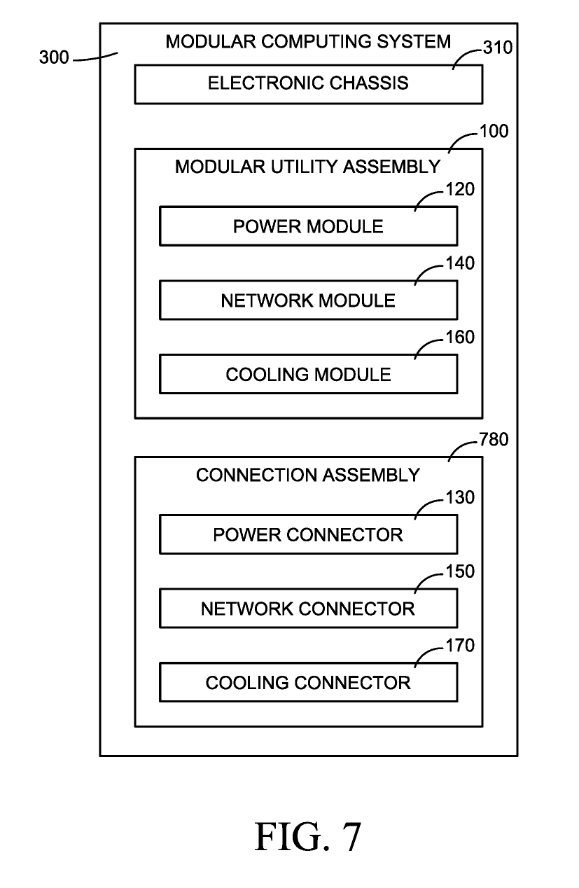

FIG. 7 illustrates a block diagram of the modular computing system 300 according to a further example. The modular computing system includes a modular utility assembly 100, an electronic chassis 310, and a connection assembly 780. The modular utility assembly 100 including a power module 120, a network module 140, and a cooling module 160. The electronic chassis 310 to receive an electronic module 290 and connect the electronic module 290 to the power module 120, network module 140, and cooling module 160. The connection assembly 780 includes a power connector 130 to interchangeably connect the power module 130 and the electronic module 290, a network connector 150 to interchangeably connect the network connector 150 and the electronic module 290, and a cooling connector 170 to interchangeably connect the cooling connector 170 to the electronic module 290.

FIG. 8-9 illustrates schematic views of the system of FIG. 7 according to an example. An electronic module 290 is illustrated. The electronic module 290 includes the power connector 130, the network connector 150, and the cooling connector 170. The utilities provide for easy swapping of replacement components to make the modular computing system 300 scalable and reduce deployment time. The utilities also increase adaptability of the system during installation, repairs, and/or upgrades.

The power connector 130, illustrated as a direct current power supply 832 and a controller 834. The direct current power supply 832 to provide power to the electronic module 290 and/or other components, such as the fans 866, which provide air cooling. For example, the power connector 130 may include high voltage direct current wiring and/or power circuits safely contained within the power module 120. The power connector 130 may further include a controller 834 to manage the direct current power supply 832.

The electronic module 290 includes the network connector 150 illustrated as optical cables 951 and connectors 850, which may be used to form the connections. The network connector 150 may protect the delicate optical fibers by pre-building network modules 140 and placing it in a network connector 150 or shell. For example, FIGS. 8-9 illustrates the network connector 150 as a floating optical connector 850. The optical connectors may include a male optical connector that connects to a plenum that is a female connector. The optical cables 951 and fabrics may be contained in optical plenums 940. Moreover, the optical cables 951 may be pigtailed to provide redundancy.

The cooling connector 170 includes a liquid connector 271 and an air connector 276. The liquid connector 271 connects to a liquid cooling module 261. The liquid connector 271 mates the liquid cooling module 261 with the electronic module 290. The liquid connector 271 comprises a blind mate connector. For example, the blind mate connector may include a dripless valve 873 connected to each of the supply blind mate connector 872 and the return blind mate connector 874. The dripless valve 873 mates with the liquid supply 262 and liquid return 264 of the liquid cooling module 261.

The air connector 276 to connect to an air cooling module. The air connector 276 to mate the air cooling module with the electronic module 290. The air connector 276 comprises a blind mate connector.

The present disclosure has been described using non-limiting detailed descriptions of examples thereof and is not intended to limit the scope of the present disclosure. It should be understood that features and/or operations described with respect to one example may be used with other examples and that not all examples of the present disclosure have all of the features and/or operations illustrated in a particular figure or described with respect to one of the examples. Variations of examples described will occur to persons of the art. Furthermore, the terms “comprise,” “include,” “have” and their conjugates, shall mean, when used in the present disclosure and/or claims, “including but not necessarily limited to.”

It is noted that some of the above described examples may include structure, acts or details of structures and acts that may not be essential to the present disclosure and are intended to be exemplary. Structure and acts described herein are replaceable by equivalents, which perform the same function, even if the structure or acts are different, as known in the art. Therefore, the scope of the present disclosure is limited only by the elements and limitations as used in the claims.

What is claimed is:

1. A modular utility assembly comprising:
a power module including a power connector to mate with and provide power to an electronic module;
a network module including a network connector to mate with and provide a network connection between the network module and the electronic module; and
a cooling module including a cooling connector to mate with and connect to a cooling component on the electronic module.

2. The modular utility assembly of claim herein the cooling module comprises a liquid cooling module.

3. The modular utility assembly of claim 1, wherein the cooling module comprises an air cooling module.

4. The modular utility assembly of claim 1, wherein each of the power module, the network module, and the cooling module comprise a connection to at least one electronic module.

5. The modular utility assembly of claim 1, wherein each of the power module, the network module, and the cooling module comprise a connection to a plurality of electronic modules.

6. A modular computing system comprising:
a modular utility assembly including a power module, a network module, and a cooling module, each including a set of blind mate connectors;
an electronic chassis to receive an electronic module and connect the electronic module to the modular utility assembly via the set of blind mate connectors; and
a support structure to receive the modular utility assembly and the electronic chassis.

7. The modular computing system of claim 6, wherein the electronic chassis accepts a set of electronic modules with integrated dry disconnect cooling fittings.

8. The modular computing system of claim 6, further comprising a cooling manifold to provide a fluid to the modular utility assembly.

9. The modular computing system of claim 6, wherein the power module comprises a set of linkable power modules.

10. The modular computing system of claim 6, wherein the cooling module comprises a liquid cooling module that includes monitors selected from at least one of the following: a valve, a liquid breaker, a flow and pressure gauge, and a temperature sensor.

11. The modular computing system of claim 6, wherein the modular utility assembly comprises a display device to provide indicators on the status of the modular computing system and modules connected thereto.

12. The modular computing system of claim 6, wherein the network module comprises a removal request button to coordinate removal and replacement of the modules connected thereto.

13. The modular computing system comprising:
a modular utility assembly including a power module, a network module, and a cooling module;
an electronic chassis to receive an electronic module and connect the electronic module to the power module, network module, and cooling module; and
a connection assembly including:
a power connector to interchangeably connect the power module and the electronic module,
a network connector to interchangeably connect the network module and the electronic module, and
a cooling connector to interchangeably connect the cooling module and the electronic module.

14. The modular computing system of claim 13, wherein the cooling connector comprises:
a liquid connector to connect to a liquid cooling module, the liquid connector to mate the liquid cooling module with the electronic module; and
an air connector to connect to an air cooling module, the air connector to mate the air cooling module with the electronic module.

15. The modular computing system of claim 13, wherein the modular utility assembly includes cooling modules with integrated dry disconnect fittings.
